(19) United States
(12) Patent Application Publication
(10) Pub. No.: US 2021/0328091 A1
(43) Pub. Date: Oct. 21, 2021

(54) APPARATUS FOR SEPARATING A SOLAR CELL INTO TWO OR MORE SOLAR CELL PIECES, SYSTEM FOR THE MANUFACTURE OF AT LEAST ONE SHINGLED SOLAR CELL ARRANGEMENT, AND METHOD FOR SEPARATING A SOLAR CELL INTO TWO OR MORE SOLAR CELL PIECES

(71) Applicant: APPLIED MATERIALS ITALIA S.R.L.

(72) Inventor: Daniele GISLON, Santa Maria Di Sala - Venice (IT)

(73) Assignees: APPLIED MATERIALS ITALIA S.R.L., San Biagio di Callalta (TV) (IT); APPLIED MATERIALS ITALIA S.R.L., San Biagio di Callalta (TV) (IT)

(21) Appl. No.: 16/329,888

(22) PCT Filed: Oct. 20, 2017
(86) PCT No.: PCT/EP2017/076897

§ 371 Date: Mar. 1, 2019

(51) Int. Cl. H01L 31/18

(52) U.S. Cl. CPC H01L 31/188; H02S 20/25

(57) ABSTRACT

The present disclosure provides an apparatus for separating a solar cell into two or more solar cell pieces. The apparatus includes a moveable arrangement, a separation device attached to the moveable arrangement, and a holding device attached to the moveable arrangement via one or more elastic elements.

### FIELD

Embodiments of the present disclosure relate to an apparatus for separating a solar cell into two or more solar cell pieces, a system for the manufacture of at least one shingled solar cell arrangement, and a method for separating a solar cell into two or more solar cell pieces. Embodiments of the present disclosure particularly relate to an apparatus, system and method for the manufacture of shingled solar cell arrangements.

### BACKGROUND

Solar cells are photovoltaic devices that convert sunlight directly into electrical power. An efficiency of the solar cells can be affected by an active area on a front surface of the solar cell that is exposed to light for converting sunlight into electrical power. The active area can be reduced due to the presence of electrical contacts, such as fingers and/or busbars, on the front surface of the solar cells. The presence of the electrical contacts on the front surface of the solar cells can thus reduce a module power of a solar cell module consisting of the solar cells.

Shingled solar cell arrangements can increase an output power of a solar cell module. The increase in the output power can be affected by a quality of a manufacturing process, such as a quality of the elements used to assemble the shingled solar cell arrangement. Further, a proper assembling of the shingled solar cell arrangement can be cumbersome, and a throughput and/or yield can be low.

In view of the above, new apparatuses for separating a solar cell into two or more solar cell pieces, systems for the manufacture of at least one shingled solar cell arrangement, and methods for separating a solar cell into two or more solar cell pieces that overcome at least some of the problems in the art are beneficial. The present disclosure particularly aims to improve a manufacturing process of solar cell arrangements.

### SUMMARY

In light of the above, an apparatus for separating a solar cell into two or more solar cell pieces, a system for the manufacture of at least one shingled solar cell arrangement, and a method for separating a solar cell into two or more solar cell pieces are provided. Further aspects, benefits, and features of the present disclosure are apparent from the claims, the description, and the accompanying drawings.

According to an aspect of the present disclosure, an apparatus for separating a solar cell into two or more solar cell pieces is provided. The apparatus includes a moveable arrangement, a separation device attached to the moveable arrangement, and a holding device attached to the moveable arrangement via one or more elastic elements.

According to another aspect of the present disclosure, a system for the manufacture of at least one shingled solar cell arrangement is provided. The system includes the apparatus for separating a solar cell into two or more solar cell pieces according to the embodiments described herein, and a support arrangement, wherein the support arrangement includes at least one of a first support configured for supporting the solar cell and a second support configured for supporting at least one solar cell piece of the two or more solar cell pieces.

According to a further aspect of the present disclosure, a method for separating a solar cell into two or more solar cell pieces is provided. The method includes moving a moveable arrangement towards the solar cell, contacting a first portion of a first surface of the solar cell with a holding device attached to the moveable arrangement via one or more elastic elements, and after contacting the first portion with the holding device, contacting a second portion of the first surface with a separation device attached to the moveable arrangement to divide the solar cell into the two or more solar cell pieces.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIGS. 1A and B show schematic side views of an apparatus for use in the manufacture of a solar cell arrangement according to embodiments described herein;

FIG. 2 shows a schematic top view of an apparatus for use in the manufacture of a solar cell arrangement according to embodiments described herein;

FIG. 3A shows a cross-sectional view of an apparatus for use in the manufacture of a solar cell arrangement according to further embodiments described herein;

FIG. 3B shows a perspective view of the apparatus of FIG. 3A;

FIG. 4 shows a flow chart of a method for separating a solar cell into two or more solar cell pieces according to embodiments described herein;

FIG. 5 shows a schematic view of a system for the manufacture of at least one shingled solar cell arrangement according to embodiments described herein;

FIG. 6 shows a schematic view of a shingled solar cell manufactured using the apparatuses, systems and methods according to the embodiments described herein;

FIG. 7A shows a schematic side view of a portion of the system for the manufacture of at least one shingled solar cell arrangement according to embodiments described herein;

FIG. 7B shows a schematic top view of a portion of the system for the manufacture of at least one shingled solar cell arrangement according to further embodiments described herein;

FIG. 8 shows a schematic view of overlapping solar cell pieces on a support device according to embodiments described herein;

FIG. 9A shows a schematic view of a system for the manufacture of at least one shingled solar cell arrangement according to further embodiments described herein; and

FIG. 9B shows a schematic view of a system for the manufacture of at least one shingled solar cell arrangement according to yet further embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Shingled solar cell arrangements can increase an output power of a solar cell module. The increase in the output power can be affected by a quality of a manufacturing process, such as a quality of the elements used to assemble the shingled solar cell arrangement. Further, a proper assembling of the shingled solar cell arrangement can be cumbersome, and a throughput and/or yield can be low.

The present disclosure mechanically holds and separates a solar cell. The holding device and the separation device are moved together to hold and separate the solar cell. The holding device is biased such that a predetermined holding force is exerted on the solar cell. A well-defined, smooth and accurate breaking edge can be achieved. A quality of the solar cell pieces used to assemble a solar cell arrangement, such as a shingled solar cell arrangement, can be improved and an output power can be increased.

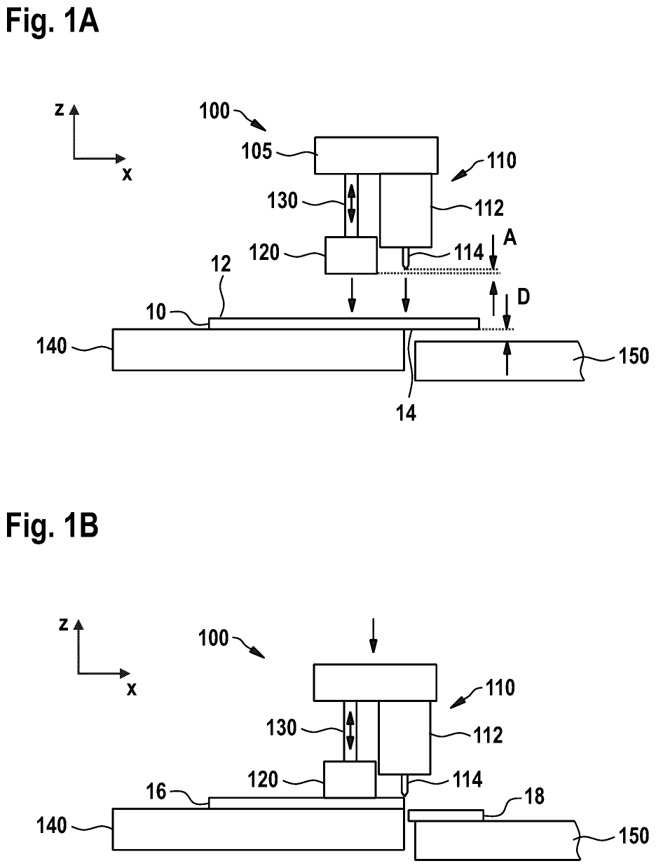

FIGS. 1A and B show schematic side views of an apparatus 100 for use in the manufacture of a solar cell arrangement, such as a shingled solar cell arrangement, according to embodiments described herein.

The apparatus 100 includes a moveable arrangement 105, a separation device 110 attached to the moveable arrangement 105, and a holding device 120 attached to the moveable arrangement 105 via one or more elastic elements 130. The holding device 120 is biased via the one or more elastic elements 130 such that a predetermined holding force is exerted on the solar cell. A well-defined, smooth and accurate breaking edge can be achieved.

The holding device 120 and the separation device 110 are both connected to the same moveable arrangement. In some embodiments, the moveable arrangement 105 has one moveable body, wherein the separation device 110 and the holding device 120 are attached to the one moveable body. In other embodiments (not shown) the moveable arrangement has a first moveable body and a second moveable body, which may be separate from each other. The separation device can be attached to the first moveable body and the holding device can be attached to the second moveable body. The first moveable body and the second moveable body can be independently moveable. In the latter case, the apparatus may include a first actuator configured to move the first moveable body and a second actuator configured to move the second moveable body. The first actuator and the second actuator can be linear actuators, such as linear motors.

The separation device 110 can be fixedly mounted to the moveable arrangement 105 such that no relative movement between the moveable arrangement 105 and the separation device 110 can occur. In particular, according to some embodiments, the separation device 110 can be immovably attached to the moveable arrangement 105. To the contrary, the holding device 120 is attached to the moveable arrangement 105 via the one or more elastic elements 130 such that a relative movement between the moveable arrangement 105 and the holding device 120 can occur e.g. by compression of the one or more elastic elements 130. In other words, the holding device 120 can be configured to be moveable with respect to the moveable arrangement 105 and/or the separation device 110.

The moveable arrangement 105 can be configured to move the holding device 120 and the separation device 110 such that the holding device 120 contacts the solar cell before the separation device 110 contacts the solar cell 10 to divide the solar cell 10 into the two or more pieces. In some implementations, the one or more elastic elements 130 can be configured to provide a holding force for holding the solar cell 10 at a support arrangement, such as a first support 140 of the support arrangement. In particular, the one or more elastic elements 130 can provide a well-defined holding force acting on the solar cell 10. A smooth and accurate breaking edge can be achieved.

According to some embodiments, which can be combined with other embodiments described herein, the one or more elastic elements 130 are springs, such as coil springs or leaf springs. However, the present disclosure is not limited thereto, and other kinds of elastic elements suitable to provide the holding force for holding the solar cell at a support arrangement can be used.

The separation device 110 can be configured to mechanically contact a first surface 12 of a solar cell 10 to divide the solar cell 10 into two or more solar cell pieces. The holding device 120 can be configured to mechanically contact the first surface 12 of the solar cell 10 to hold the solar cell 10 e.g. at the support arrangement at least while the solar cell 10 is divided into the two or more solar cell pieces, such as a first solar cell piece 16 and a second solar cell piece 18.

The separation device 110 can be configured to mechanically contact a first portion of the first surface 12 of the solar cell 10. The holding device 120 can be configured to mechanically contact a second portion of the first surface 12 of the solar cell 10. The first portion can correspond to a contact area of the separation device 110 and the first surface 12. The second portion can correspond to a contact area of the holding device 120 and the first surface 12. The first portion and the second portion can be spaced apart from each other. In some implementations, the spacing between the first portion and the second portion can be less than a width of each of the two or more solar cell pieces. The width of a solar cell piece can be defined perpendicular to a breaking line or breaking edge defining a respective solar cell piece.

According to some embodiments, the solar cell 10 has the first surface 12 and a second surface 14 opposite the first surface 12. The first surface 12 can be a front side or front surface of the solar cell 10 and the second surface 14 can be a back side or back surface of the solar cell 10. In some implementations, the solar cell 10 can have one or more conductive patterns, such as fingers and/or busbars, provided thereon. In particular, the term “solar cell” can refer to a finished or nearly finished solar cell instead of, for example, an unprocessed semiconductor substrate. The fingers and/or busbars can be deposited on the first surface 12, for example, using a printing technique such as screen printing. Optionally, the solar cell 10 can have one or more contacts, such as back contacts, on the second surface 14.

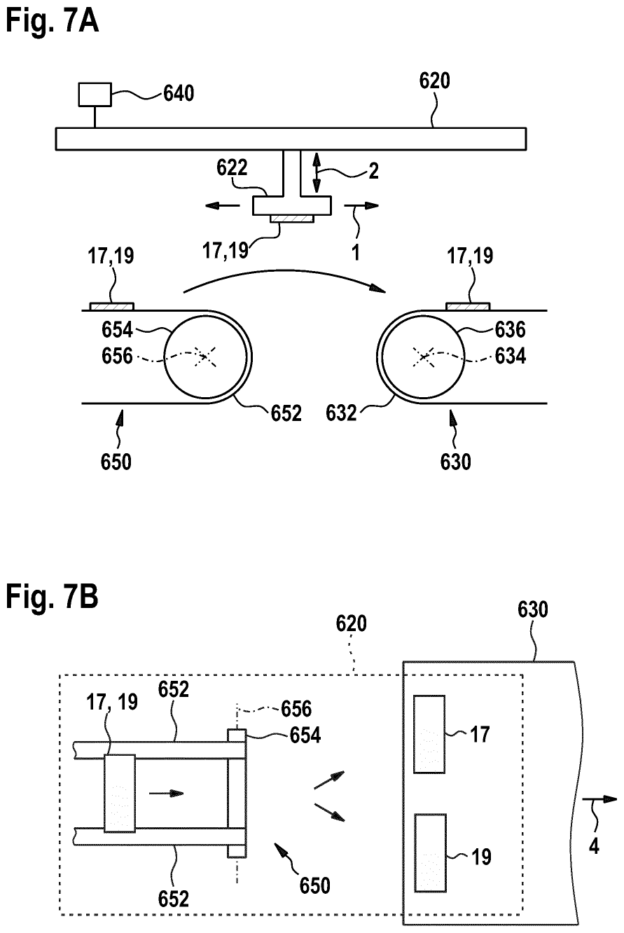

According to some embodiments, which can be combined with other embodiments described herein, the support arrangement includes a first support 140 configured to support the solar cell 10 and a second support 150 configured to support at least one solar cell piece of the two or more solar cell pieces obtained from the solar cell 10. According to an aspect of the present disclosure, a system for the manufacture of at least one shingled solar cell arrangement includes the apparatus for separating a solar cell into two or more solar cell pieces and the support arrangement. In some implementations, the system can include at least one positioning device configured for positioning the two or more solar cell pieces on a support device to assemble the at least one shingled solar cell arrangement, as is illustrated in FIGS. 7A and B.

The first support 140 can be configured to support the second surface 14 of the solar cell 10. As illustrated in FIG. 1A, the first support 140 can support the solar cell 10 such that the solar cell 10 protrudes over an edge of the first support 140 by a predetermined distance, particularly during the separation process. The predetermined distance can be essentially equal to, or greater than, the width of the solar cell piece that is to be separated from the solar cell 10. For example, the separation device 110 can be configured to contact the solar cell 10 at, or away from, an edge or edge portion of the first support 140 to break the solar cell piece off the solar cell 10, as is exemplarily shown in FIG. 1B.

The solar cell piece that has been separated from the solar cell 10, such as the second solar cell piece 18, can be collected by the second support 150. The remaining solar cell piece of the solar cell (also referred to as “remaining solar cell”), such as the first solar cell piece 16, can remain on the first support 140. In some implementations, one or more further solar cell pieces can be separated from the solar cell piece of the remaining solar cell on the first support 140, such as from the first solar cell piece 16. In particular, the separation device 110 can be configured to separate the solar cell 10 into two or more solar cell pieces. In particular, the separation device 110 can create smaller cells (solar cell pieces or solar cell elements) starting from the (big) solar cell. The two or more solar cell pieces may have essentially the same dimensions, such as lengths and/or widths. According to some embodiments, the solar cell 10 can be divided into any suitable number of solar cell pieces, such as two, three, four, five, six, or even more solar cell pieces.

In some implementations, the first support 140 is a first transportation device, such as a first belt conveyor, configured for transportation of the solar cell 10 to the separation device 110. The second support 150 can be a second transportation device, such as a second belt conveyor, configured for transportation of the two or more solar cell pieces away from the separation device 110 e.g. towards the at least one positioning device.

According to some embodiments, the second support 150 is offset by an amount D with respect to the first support 140 in an offset direction, which can be essentially perpendicular to the first surface 12 of the solar cell 10. The offset direction can be an essentially vertical direction (e.g., the z-direction). The solar cell piece, such as the second solar cell piece 18, can fall onto the second support 150 when the solar cell piece is separated from the solar cell 10 or remaining solar cell.

According to some embodiments, which can be combined with other embodiments described herein, the separation device 110 includes a body 112 and a contact element 114 connected to the body 112. The body 112 and the contact element 114 can be connected to the moveable arrangement 105, such as a linear motor. In some embodiments, the body 112 can be omitted and the contact element 114 can be directly connected to the moveable arrangement 105.

The contact element 114 can be configured to contact the first surface 12 of the solar cell 10 to divide the solar cell 10 into the two or more solar cell pieces. The contact element 114 can also be referred to as “cleaving device”. The contact element 114 and the body 112 can be provided as separate entities, or can be integrally formed from a single piece of material, such as a plastic material.

In some implementations, the contact element 114 can be a blade or an element with a sharp tip configured to contact the solar cell 10 for cleaving and dividing the solar cell 10. According to some embodiments, the contact element 114 can be made of a plastic material. However, the present disclosure is not limited thereto, and the contact element 114 can be made of other materials, such as ceramics and/or metal.

In some implementations, the moveable arrangement 105 can be configured to move the separation device 110 towards the solar cell 10, for example, in a quick motion, in order to provide a sharp dividing line at the solar cell 10. For example, the apparatus 100, and particularly the moveable arrangement 105, can include at least one actuator, such as a linear actuator, configured to move the moveable arrangement 105 at least in a first direction essentially perpendicular to a surface of the solar cell 10, such as essentially perpendicular to the first surface 12.

The first direction can be an essentially vertical direction, such as the z-direction. For example, the moveable arrangement 105 can push the holding device 120 and the contact element 114 against the solar cell 10 in order to respectively hold and cleave the solar cell 10. According to some embodiments, the moveable arrangement 105 can be movable substantially vertically towards and away from the solar cell 10, e.g., in an upwards and downwards movement. The upwards and downwards movement can be repeated in predetermined intervals to divide the solar cell 10 into the two or more solar cell pieces.

The apparatus 100 includes the holding device 120 which may be configured to mechanically contact the first surface 12 of the solar cell 10 to hold the solar cell 10 at the support arrangement, and particularly at the first support 140. The holding device 120 can press or push against the first surface 12 such that the second surface 14 is pressed against the first support 140. By fixing the solar cell 10 to the support arrangement, e.g., by holding the solar cell 10 down at and against the support arrangement, a reliable separation process can be provided. The holding device 120 may include, or be, an elastic holding element configured to mechanically contact the first surface 12 of the solar cell 10. For example, the elastic holding element may be made of rubber. The elasticity of the holding element may prevent damaging of the solar cell 10.

In some implementations, the holding device 120 can be moveable in a direction essentially perpendicular to the first surface 12 of the solar cell 10, e.g., in an essentially vertical direction, such as the z-direction. The holding device 120 can contact the solar cell before the contact element 114 contacts the solar cell 10, such that the holding force is already exerted on the solar cell 10 before the cleaving action takes place. Once the holding device 120 is in contact with the solar cell 10, the holding device 120 may remain stationary while the separation device 110 still moves. The term “essentially perpendicular” relates to an essentially perpendicular orientation e.g. of the first surface 12 and the first direction, wherein a deviation of a few degrees, e.g. up to 10° or even up to 15°, from an exact perpendicular orientation is still considered as “essentially perpendicular”.

According to some embodiments, an end of the holding device 120 and an end of the separation device 110 such as the contact element 114 facing the solar cell 10 can be offset by an offset amount A in the first direction when there is no contact between the solar cell 10 and the holding device 120. The offset amount A can be in a range between 0 and 20 mm, specifically in a range between 0 and 15 mm, and more specifically in a range between 0 and 10 mm. The offset amount A of 0 means that the holding device 120 and the end of the separation device 110 are at the same height. The holding device 120 and the separation device 110 can contact the substrate at essentially the same time. i.e., essentially simultaneously. In some implementations, the offset amount A is larger than 0 and less than 20 mm, specifically less than 15 mm, and more specifically less than 10 mm. The offset can ensure that the holding device 120 contacts the solar cell before the separation device 110 does. In other words, the holding force is already in place when the separation device 110 cleaves the solar cell 10 into pieces.

In some embodiments, the holding device 120 can be configured to essentially prevent a movement of the solar cell 10 in a plane essentially parallel to the first surface 12 of the solar cell 10, e.g., the x-y-plane, which can be an essentially horizontal plane. For example, the holding device 120 can provide a frictional force against the first surface 12 such that the solar cell 10 cannot move in the plane essentially parallel to the first surface 12. An accurate alignment of the solar cell during the separation process can be achieved.

According to some embodiments, which can be combined with other embodiments described herein, the apparatus 100, and particularly the separation device 110, further includes at least one solar cell perforation device configured for providing one or more predetermined breaking points or predetermined breaking lines on the first surface 12 of the solar cell 10. For example, the at least one solar cell perforation device includes, or is, a laser. The at least one solar cell perforation device can be configured to perforate the solar cell 10 to define the breaking points or lines for the two or more solar pieces before the solar cell 10 is separated into the two or more solar cell pieces by the separation device 110.

The at least one solar cell perforation device can be configured to generate one or more predetermined breaking points or lines on the solar cell 10 such that the solar cell 10 can be easily broken into the two or more solar cell pieces. For example, the at least one solar cell perforation device can be configured to provide a plurality of predetermined breaking points along a substantially straight line on the solar cell that defines a separation line between two adjacent solar cell pieces. In another example, the at least one solar cell perforation device can be configured to provide a continuous predetermined breaking line on the solar cell 10 that defines the separation line between two adjacent solar cell pieces. The perforation of the solar cell 10 before the cleaving action can provide for a straight and sharp edge at the solar cell piece that is broken off the solar cell 10. In particular, for hypercell creation, the solar cell 10 can be previously lasered in order to cleave the solar cell 10 into the smaller cells in a controlled manner.

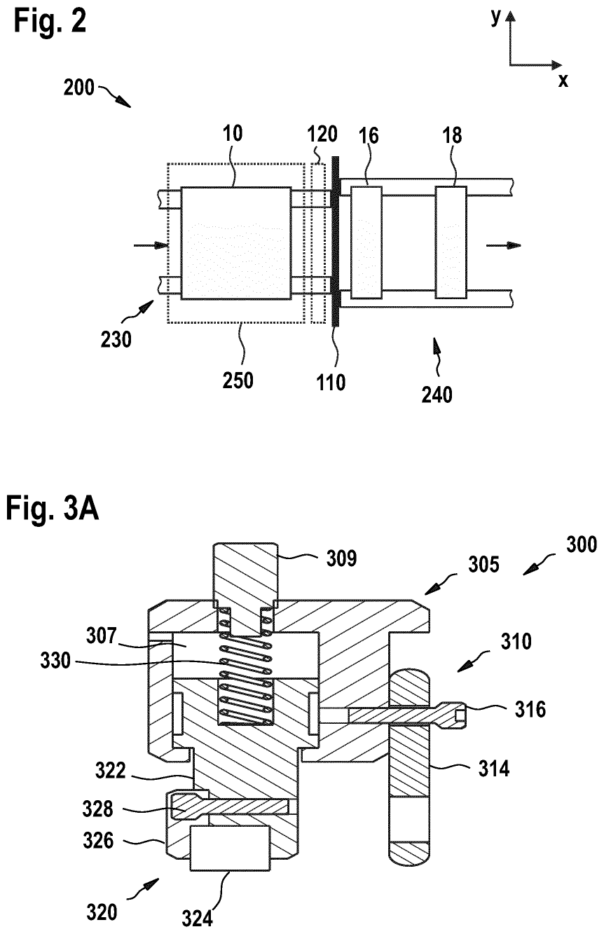

FIG. 2 shows a schematic top view of an apparatus 200 for use in the manufacture of a solar cell arrangement, such as a shingled solar cell arrangement, according to embodiments described herein.

According to some embodiments, which can be combined with other embodiments described herein, the first support is a first transportation device 230 configured for transportation of the solar cell to the separation device 110. The second support can be a second transportation device 240 configured for transportation of the two or more solar cell pieces, such as the first solar cell piece 16 and the second solar cell piece 18, away from the separation device 110. The first transportation device 230 can be configured for transportation of the solar cell 10 in a first transport direction. Likewise, the second transportation device 240 can be configured for transportation of the two or more solar cell pieces in a second transport direction. The first transport direction and the second transport direction can be essentially parallel. In some embodiments, the first transport direction and/or the second transport direction can be essentially horizontal directions.

In some implementations, the first transportation device 230 and/or the second transportation device 240 can be belt conveyors configured for conveying the solar cell 10 and/or solar cell pieces, as is shown in the top view of FIG. 2. The first transportation device 230 and/or the second transportation device 240 can each have two or more belts spaced apart from each other. In particular, a gap can be provided between the two or more belts.

In some embodiments, an inspection system can be provided, for example, below the first transportation device 230 and/or the second transportation device 240, to determine, for example, a position of the solar cell 10 and/or the two or more solar cell pieces on the respective transportation device. The gap between the two or more belts can ensure that the inspection system, and particularly a camera thereof, can see the solar cell or solar cell pieces located on the first transportation device 230 and/or the second transportation device 240. Further, a contact area between the solar cell 10 or solar cell pieces and the respective transportation device can be minimized to avoid damaging the solar cell 10 or solar cell pieces.

According to some embodiments, which can be combined with other embodiments described herein, the apparatus 200 further includes an alignment device 250 configured to align the solar cell 10 before the solar cell 10 is divided into the two or more solar cell pieces. The alignment device 250 can be a centering device, such as a mechanical centering device, configured to center or align the solar cell 10 which is to be divided into the two or more solar cell pieces. For example, the centering device can be provided at the separation device 110 to center or align the solar cell 10 with respect to the separation device 110. In particular, the solar cell 10 can be centered or aligned before the solar cell is inputted into the separation device 110.

In some implementations, the alignment device 250, the holding device 120, and the separation device 110 can be sequentially arranged along the first transport direction. For example, the alignment device 250, the holding device 120, and the separation device 110 can be provided at the first support, which can be the first transportation device 230.

The solar cell 10 is separated into two or more solar cell pieces. FIG. 2 exemplarily illustrates two solar cell pieces, namely the first solar cell piece 16 and the second solar cell piece 18, and further illustrates a fresh solar cell on the first transportation device 230, from which no solar cell pieces have been separated yet. It is to be understood that the apparatus 200 can be configured for separating each solar cell 10 into a suitable number of solar cell pieces, such as two, three, four, five, six, or even more solar cell pieces.

The first transportation device 230 can transport the solar cell 10 to the separation device such that the solar cell 10 can be divided into the two or more solar cell pieces. In some implementations, the first transportation device 230 is configured for positioning the solar cell 10 with respect to the separation device 110, and particularly the contact element, such that the two or more solar cell pieces can be broken off the solar cell 10 in a controlled and well-defined manner. For example, the first transportation device 230 can be configured to position the solar cell 10 such that a breaking line or breaking edge is positioned at, or near, the contact element. In particular, the solar cell 10 can be positioned such that the contact element contacts the first surface 12 of the solar cell 10 adjacent to the breaking line to break off the respective solar cell piece.

In some implementations, a movement of the first transportation device 230 in the first transport direction and a movement of the separation device 110, such as a movement of the body and the contact element, can be synchronized. For example, the contact element can repeatedly move upwards and downwards, wherein the first transportation device 230 can position the solar cell 10 underneath the contact element e.g. during the upward movement of the body and the contact element. The first transportation device 230 can be configured to move intermittently such that the solar cell 10 or the remaining solar cell is stationary below the contact element when the contact element contacts the first surface to break off a solar cell piece.

According to some embodiments, the second transportation device 240 can move continuously in the second transport direction. In other words, a movement of the second transportation device 240 and a movement of the first transportation device 230 and/or the separation device may not be synchronized. However, the present disclosure is not limited thereto, and a movement of the second transportation device 240 and a movement of the first transportation device 230 and/or the separation device 110 may be synchronized.

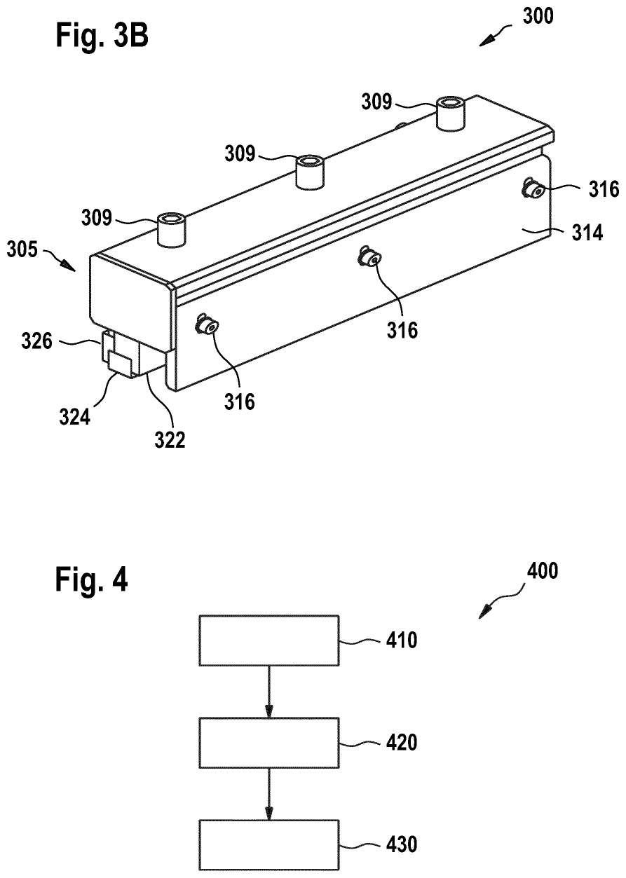

FIG. 3A shows a cross-sectional view of an apparatus 300 for use in the manufacture of a solar cell arrangement according to further embodiments described herein. FIG. 3B shows a perspective view of the apparatus 300 of FIG. 3A. The apparatus 300 may be referred to as “cutter group”.

The separation device 310 and the holding device 320 are attached to the moveable arrangement 305. For example, the separation device 310, and particularly the contact element 314, can be secured to the moveable arrangement 305 using one or more first fastening devices 316, such as screws. The separation device 310 can be immovably fixed to the moveable arrangement 305 while the holding device 320 can be moveably attached to the moveable arrangement 305 via the one or more elastic elements 330, such as one or more springs.

According to some embodiments, which can be combined with other embodiments described herein, the holding device 320 includes a connection device 322 and a holding element 324. The holding element 324, which may also be referred to as “contact element”, may be made of an elastic material, such as rubber. The holding element 324 may be attached to the connection device 322 e.g. using a holding unit 326, which may be a clamping device. The holding unit 326 may be releasably attached to the connection device 322 using one or more second fastening devices 328, such as screws. The holding element 324 may be replaced e.g. if the holding element 324 is damaged.

In some implementations, a first end of the elastic element 330 is connected to the holding device 320, such as the connection device 322. A second end of the elastic element 330 may be connected to the moveable arrangement 305. The moveable arrangement 305 may include an adjustment device 309 abutting against the second end of the elastic element 330. For example, the moveable arrangement 305 may include a threaded hole and the adjustment device 309 may be a screw insertable into the threaded hole. By rotating the adjustment device 309, the bias of the one or more elastic elements 330 and thus the holding force can be adjusted.

According to some embodiments, which can be combined with other embodiments described herein, the moveable arrangement 305 includes a guide configured to guide the movement of the holding device 320 e.g. when the holding device 320 contacts the solar cell and the one or more elastic elements 130 are compressed. For example, the moveable arrangement 305 can include a reception or guide space 307 into which at least a portion of the holding device 320 is inserted such that the movement of the holding device 320 is guided. In some implementations, the connection device 322 may be inserted in the reception or guide space 307 so as to slide within the reception or guide space 307 e.g. in the first direction.

FIG. 4 shows a flow chart of a method 400 for separating a solar cell into two or more solar cell pieces according to embodiments described herein. The method 400 can be implemented using the apparatuses and systems according to the present disclosure.

The method 400 includes, in block 410, moving a moveable arrangement towards the solar cell, in block 420, contacting a first portion of a first surface of the solar cell with a holding device attached to the moveable arrangement via one or more elastic elements, and in block 430, after contacting the first portion with the holding device, contacting a second portion of the first surface with a separation device attached to the moveable arrangement to divide the solar cell into the two or more solar cell pieces. In some implementations, the separation device is immoveable with respect to the moveable arrangement and the holding device is moveable with respect to the moveable arrangement.

The first portion and the second portion can be spaced apart from each other. In some implementations, the spacing between the first portion and the second portion can be less than a width of the two or more solar cell pieces. In some implementations, the method further includes intermittently moving the solar cell in a transport direction. The solar cell can move intermittently such that the solar cell (or the remaining solar cell) is stationary below the contact element when the contact element contacts the first surface to break off a solar cell piece.

According to embodiments described herein, the method for separating a solar cell into two or more solar cell pieces can be conducted using computer programs, software, computer software products and the interrelated controllers, which can have a CPU, a memory, a user interface, and input and output devices being in communication with the corresponding components of the apparatus.

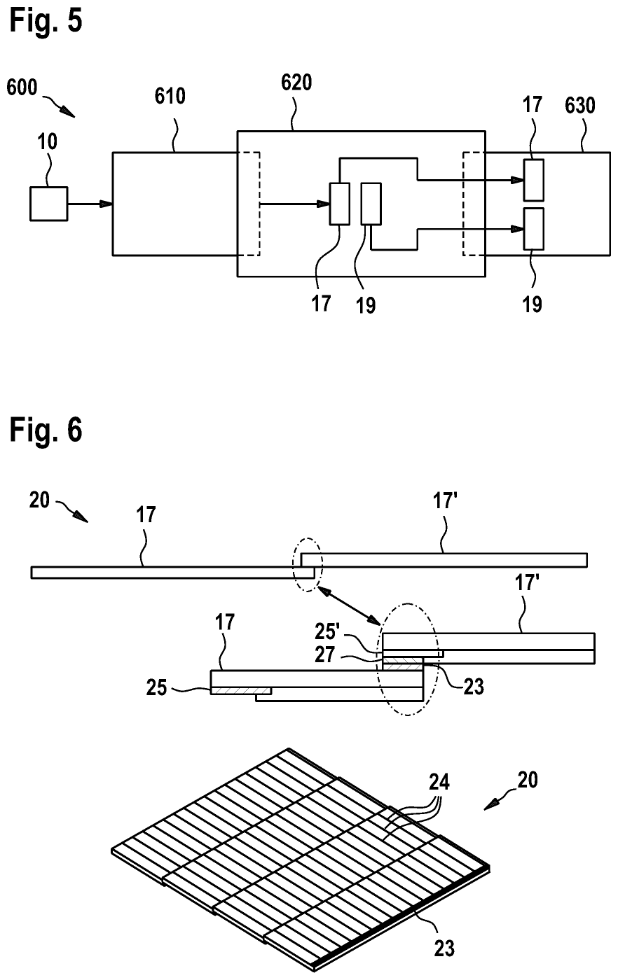

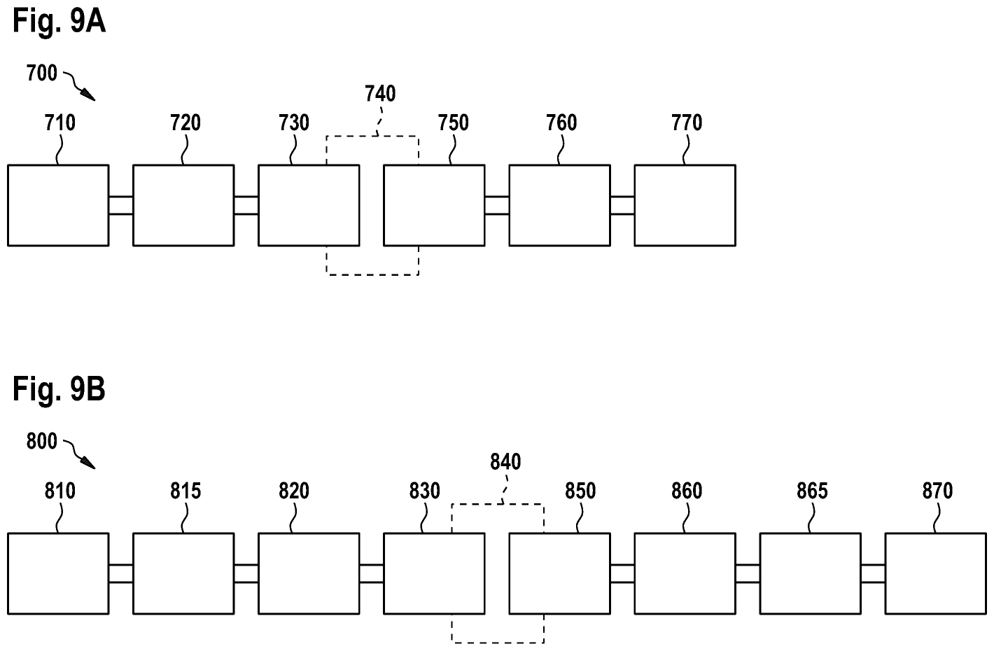

FIG. 5 shows a schematic view of a system 600 for the manufacture of at least one solar cell arrangements, such as at least two solar cell arrangements, according to embodiments described herein. The system 600 can be part of a larger production line, as is for example described with respect to FIGS. 9A and B.

The system 600 includes the apparatus 610 for separating a solar cell into two or more solar cell pieces according to the embodiments described herein, and at least one positioning device 620 configured for positioning the two or more solar cell pieces on a support device 630 to assemble the solar cell arrangement(s).

The apparatus 610 includes the separation device configured for separating a solar cell 10, such as a first solar cell, into two or more first solar cell pieces, and the at least one positioning device 620 configured for positioning at least one first solar cell piece 17 of the two or more first solar cell pieces on the support device 630 for forming a first solar cell arrangement of the at least two solar cell arrangements and for positioning at least one further or other first solar cell piece 19 of the two or more first solar cell pieces on the support device 630 for forming a second solar cell arrangement of the at least two solar cell arrangements.

The apparatus 610 divides the solar cell 10 into a plurality of solar cell pieces, wherein at least two solar cell pieces of said solar cell 10 can be allocated to two different solar cell arrangements. For example, the solar cell arrangements can be shingled solar cells, wherein solar cell pieces of one or more solar cells including the first solar cell can be allocated to the respective solar cell arrangement based on characteristics and/or quality of the individual solar cells and/or solar cell pieces. An efficiency of the solar cell arrangement can be improved, particularly since “bottlenecks” in the solar cell arrangement due to low-quality and/or high-resistance pieces can be avoided.

According to some embodiments, which can be combined with other embodiments described herein, the at least one positioning device 620 is configured to arrange a plurality of solar cell pieces, such as a plurality of first solar cell arrangement pieces, including the at least one first solar cell piece 17 on the support device 630 with adjacent solar cell pieces partly overlapping with each other to form the first solar cell arrangement. The at least one positioning device 620 can be further configured to arrange a plurality of other solar cell pieces, such as a plurality of second solar cell arrangement pieces, including the at least one other first solar cell piece 19 on the support device 630 with adjacent solar cell pieces partly overlapping with each other to form the second solar cell arrangement. Accordingly, the hypercell can be formed by smaller cells assembled as shingles. The overlapping configuration of a solar cell arrangement is further explained with respect to FIG. 7.

According to some embodiments, the apparatus 610 is configured for separating a second solar cell into two or more second solar cell pieces. The first solar cell and the second solar cell can be inputted into and/or processed by the apparatus 610 sequentially or simultaneously. In particular, the separation device can be configured for sequentially or simultaneously separating the first solar cell and the second solar cell into the two or more first solar cell pieces and the two or more second solar cell pieces, respectively. The positioning device 620 can be configured for positioning at least one second solar cell piece of the one or more second solar cell pieces on the support device 630 for forming the first solar cell arrangement together with the at least one first solar cell piece 17, and can be configured for positioning at least one other second solar cell piece of the two or more second solar cell pieces on the support device 630 for forming the second solar cell arrangement together with the at least one other first solar cell piece 19.

In particular, a plurality of solar cells can be divided into solar cell pieces, wherein each solar cell piece can be allocated to either the first solar cell arrangement or the second solar cell arrangement. The solar cell pieces of the first solar cell arrangement can particularly include the at least one first solar cell piece 17 and the at least one second solar cell piece, and can optionally further include one or more solar cell pieces of further solar cells, such as a third, fourth, etc. solar cell. The solar cell pieces, e.g., of the second solar cell arrangement can include the at least one other first solar cell piece and the at least one other second solar cell piece, and can optionally further include one or more solar cell pieces, e.g., of further solar cells, such as the third, fourth, etc. solar cell.

In some implementations, the system 600 is configured to allocate each solar cell piece, such as the solar cell pieces of the two or more first solar cell pieces, to either the first solar cell arrangement or the second solar cell arrangement based on one or more properties (e.g., geometric and/or physical properties) of the respective solar cell piece. For example, each solar cell piece of the plurality of solar cells can be allocated to either the first solar cell arrangement or the second solar cell arrangement, for example, based on one or more characteristics or properties of the respective solar cell piece. The one or more characteristics or properties of the solar cell piece may be selected from the group consisting of geometric shape, electrical properties, optical properties, printing quality, and any combination thereof.

In some implementations, the at least two solar cell arrangements, such as the first solar cell arrangement and the second solar cell arrangement, can be arranged in parallel (i.e., next to each other) on the support device 630, for example, along a transport direction provided by the support device 630. In particular, the at least two solar cell arrangements, such as the first solar cell arrangement and the second solar cell arrangement, can be assembled simultaneously by dividing the plurality of solar cells into solar cell pieces and selectively allocating the solar cell pieces to the first solar cell arrangement and the second solar cell arrangement.

Although the example of FIG. 5 shows two solar cell arrangements on the support device 630 that are assembled in parallel, it is to be understood that the present disclosure is not limited thereto, and that any number of solar cell arrangements could be assembled in parallel. For example, the at least two solar cell arrangements can be two, three, four five, or even six solar cell arrangements, including the first solar cell arrangement and the second solar cell arrangement, that can be assembled in parallel. At least some of the solar cell arrangements can have different characteristics or quality based on the properties of the solar cell pieces which have been allocated to the individual solar cell arrangement.

FIG. 6 shows a schematic view of a solar cell arrangement 20, which is a shingled solar cell or hypercell, that can be manufactured using the apparatuses, systems and methods according to the embodiments described herein. The solar cell arrangement 20 can be used in a solar cell module, which is a packaged, connected assembly of a plurality of solar cells or solar cell arrangements.

The shingled solar cell includes a plurality of overlapping solar cell pieces. For example, the shingled solar cell can include the at least one first solar cell piece 17 and the at least one second solar cell piece 17′ of the second solar cell. The at least one first solar cell piece 17 and the at least one second solar cell piece 17′ overlap with each other. However, the present disclosure is not limited thereto, and some of the adjacent solar cell pieces of the shingled solar cell can be from the same solar cell, such as the first solar cell or the second solar cell. Adjacent solar cell pieces can overlap by less than 20%, specifically less than 10%, and more specifically less than 5% of the total surface area, such as the front side surface or back side surface, of the solar cell pieces.

In some implementations, each solar cell piece of the plurality of overlapping solar cell pieces of the solar cell arrangement 20 can have one or more conductive patterns, such as fingers 24 and/or busbars 23, provided thereon. As an example, the solar cell piece, such as the at least one first solar cell piece 17, can have a front side and a back side corresponding to the front side and the back side, respectively, of the former solar cell. Optionally, the solar cell piece can have one or more back side contacts. As exemplarily shown in FIG. 7, the at least one first solar cell piece 17 can have a first back side contact 25, and the at least one second solar cell piece 17′ can have a second back side contact 25′.

Adjacent solar cell pieces are electrically connected to each other in the overlapping region. The solar cell pieces are thus connected in series such that current generated by the individual solar cell pieces flows along the series of solar cell pieces to be collected, for example, at an end portion of the solar cell arrangement 20 (not shown). The overlapping configuration can provide solar cell arrangements having an increased output power. As an example, the busbar 23 provided on the at least one first solar cell piece 17 can be electrically connected to the second back side contact 25′ of the at least one second solar cell piece 17′. As shown in the example of FIG. 7, the separation device can be configured to separate the solar cell adjacent to the busbars of the solar cell. In other words, each solar cell piece can have a busbar, and particularly only one busbar, provided thereon, which can be located at an edge of the solar cell piece.

In some implementations, an adhesive 27, such as an electrically conductive adhesive, can be provided to connect the solar cell pieces in the overlapping region. According to some embodiments, which can be combined with other embodiments described herein, the apparatus for the manufacture of at least two solar cell arrangements includes an adhesive application device configured to apply the adhesive to the solar cell or the solar cell pieces thereof, such as the two or more first pieces, before the two or more first solar cell pieces are positioned on the support device. Two solar cell pieces can be overlapped with the adhesive being provided at one solar cell piece of the two solar cell pieces, such that the two solar cell pieces can be electrically and mechanically connected to each other. As an example, the adhesive can be in a substantially liquid form when the adhesive is applied to a solar cell or solar cell piece.

According to some embodiments, the adhesive application device can be configured to apply the adhesive on at least a portion of the conductive line pattern, such as the busbars, of the solar cell or the solar cell pieces thereof. In some implementations, the adhesive is applied before the solar cell is divided into the two or more solar cell pieces. In other implementations, the adhesive is applied to the solar cell piece(s) after the solar cell has been divided into the two or more pieces.

According to some embodiments, the adhesive is selected from the group consisting of solder, silver paste, silicone-based electrically conductive adhesive, and epoxy-based electrically conductive adhesive.

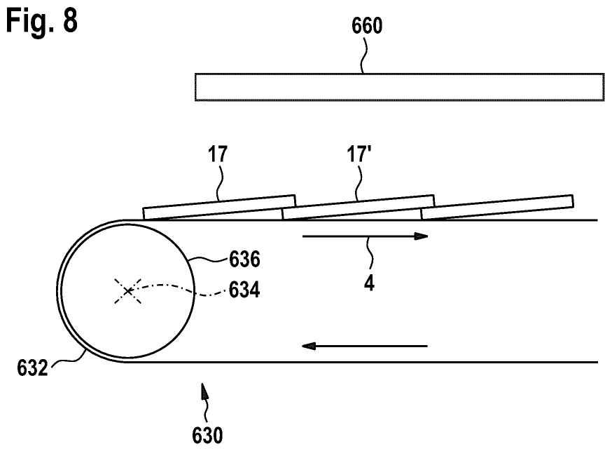

When solar cell pieces have been overlapped, for example, in the assembling of the solar cell arrangement, a drying process can be performed to dry the adhesive. In some implementations, the drying process can include a heating of the overlapping region of the two solar cell pieces using, for example, a heater such as an infrared heater. The heater is further explained with respect to FIG. 8.

FIG. 7A shows a schematic side view of a system for the manufacture of at least one shingled solar cell arrangement, such as two or more shingled solar cell arrangements, according to further embodiments described herein. FIG. 7B shows a schematic top view of the system. FIG. 8 shows a schematic view of overlapping solar cell pieces on a support device 630 according to embodiments described herein.

According to some embodiments, which can be combined with other embodiments described herein, the system includes a transport device 650 configured for transportation of the solar cell pieces of the solar cell(s), such as the two or more first solar cell pieces of the first solar cell. The transport device 650 can be the second transportation device of the apparatus according to the present disclosure. In particular, the second transportation device can be configured as described in the following. In some implementations, the transport device 650 can include, or be, a belt conveyor having a roller 654 rotatable around a first rotational axis 656 and one or more first belts 652 provided on the roller 654. The transport device 650 can have two or more belts arranged in parallel and with gaps provided between the two or more belts.

In some implementations, the first support and/or the second support of the support arrangement of the apparatus described with respect to FIGS. 1A, 1B and 2 can be provided by the transport device 650, and particularly by the one or more first belts. The separation device is not illustrated in FIGS. 7A and B.

According to some embodiments, the support device 630 can include, or be, a belt conveyor. The support device 630, e.g., the belt conveyor, can be configured to support, fix and transport the at least one solar cell arrangement, such as the first solar cell arrangement and the second solar cell arrangement. In particular, the support device 630 can be configured for transportation of the at least one solar cell arrangement in a transport direction 4, which can be an essentially horizontal direction.

The belt conveyor constituting the support device 630 can include a roller 636 rotatable around a second rotational axis 634 and one or more second belts 632 provided on the roller 636. In some implementations, the support device 630 can have two or more belts arranged in parallel and with gaps provided between the two or more belts. As an example, each belt of the two or more belts can be configured to support (only) one solar cell arrangement of two or more solar cell arrangements (for example, see FIG. 7A). In other implementations, the support device 630 has one single belt on which the two or more solar cell arrangements can be assembled in parallel (for example, see FIG. 7B).

According to some embodiments, which can be combined with other embodiments described herein, the support device 630 includes, or is, at least one of an electrostatic chuck and a vacuum chuck. The vacuum chuck can include a support surface configured to support the at least one solar cell arrangement, wherein the support surface can have at least one of holes and recesses connected to a suction device, such as a vacuum pump, in order to generate an under pressure in the holes and/or recesses to hold the solar cell arrangement at the support surface.

The at least one positioning device 620 is configured for moving or transferring the solar cell pieces of the solar cell from, for example, the transport device 650 to the support device 630. As an example, the positioning device 620 can sequentially grip or pick up the solar cell pieces from the transport device 650, move the solar cell pieces to the support device 630, optionally align the solar cell pieces, and release the solar cell pieces in a predetermined position. In particular, the positioning device 620 can be configured to arrange the solar cell pieces in an overlapping manner to form the first solar cell arrangement and the second solar cell arrangement. While the at least two solar cell arrangements are assembled on the support device 630, the support device 630, and particularly the one or more first belts having the (partially) assembled solar cell arrangements positioned thereon, can continuously move in the transport direction 4. A continuous manufacturing process can be provided.

According to some embodiments, the system includes a controller 640 configured to control the at least one positioning device 620. In particular, the controller 640 can control a movement of the positioning device 620 to move a solar cell piece to assemble a solar cell arrangement to which the solar cell piece has been allocated. As an example, the controller 640 can control the at least one positioning device 620 to move the solar cell piece to either the first solar cell arrangement or the second solar cell arrangement based on one or more properties (e.g., geometric and/or physical properties) of the piece, such as geometric shape, electrical properties, optical properties, printing quality, and any combination thereof.

According to some embodiments, which can be combined with other embodiments described herein, the at least one positioning device 620 includes a gripper 622 configured to grip and hold a solar cell piece, such as the two or more first pieces of the first solar cell. The gripper 622 can be selected from the group consisting of vacuum grippers, mechanical grippers, electrostatic grippers, electrodynamic grippers, and any combination thereof.

In some implementations, the positioning device 620 is movable in at least one of a first direction 1 and a second direction 2. The first direction 1 can be a substantially horizontal direction. The second direction 2 can be a substantially vertical direction. The positioning device 620 can be movable sequentially or simultaneously in at least one of the first direction 1 and the second direction 2. By the movement in the first direction 1 and the second direction 2, the solar cell piece held by the positioning device 620 can be moved to the support device 630 for assembling of a solar cell arrangement, such as the first solar cell arrangement and/or the second solar cell arrangement.

For example, the positioning device 620 can move in the second direction 2, for example, upwards, to pick up the solar cell piece from the transport device 650. The positioning device 620 can then move in the first direction 1, for example, forwards, to move the solar cell piece from the transport device 650 to the support device 630. The positioning device 620 can move in the second direction 2, for example, downwards, to place the solar cell piece on the support device 630. The positioning device 620 can then move in the second direction 2 and the first direction 1, for example, back to the transport device 650 to pick up another solar cell piece from the transport device 650. It is to be understood that the movement in the first direction 1 can be a movement in a forward direction and a backward direction. Likewise, the movement in the second direction 2 can be a movement in an upward direction and a movement in a downward direction.

The term “vertical direction” is understood to distinguish over “horizontal direction”. That is, the “vertical direction” relates to a substantially vertical movement, wherein a deviation of a few degrees, e.g. up to 5° or even up to 10°, from an exact vertical direction is still considered as a “substantially vertical direction”. The vertical direction can be substantially parallel to the force of gravity.

In some implementations, the system, and particularly the positioning device 620, can be configured for alignment of the solar cell piece held by the positioning device 620 before the solar cell piece is put on the support device 630. The system can use information acquired by an inspection system which can include, for example, a camera configured to detect a position and/or orientation of the solar cell piece, for example, held by the positioning device 620.

In some implementations, the positioning device 620 is movable in a plane, such as a substantially horizontal plane. Such a movement can also be referred to as “0 movement”. As an example, the positioning device 620 can be configured to adjust or align an angular orientation of a solar cell piece held by the positioning device 620 in the plane. The angular orientation of the solar cell piece can be aligned, for example, with respect to the support device 630 and/or another solar cell piece on the support device 630 with which the solar cell piece held by the positioning device 620 is to be overlapped. The solar cell arrangement can be accurately assembled, wherein a quality of the solar cell arrangement can be improved. In some implementations, the positioning device 620 can be configured to rotate the solar cell piece around a substantially vertical rotational axis by about 180°. In particular, edge pieces of pseudo-square solar cells can be brought into similar orientations. As an example, one edge piece (e.g., the front or leading edge piece) of the pseudo-square solar cell is not rotated by about 180° and the other edge piece (e.g., the back or trailing edge piece) of the pseudo-square solar cell is rotated by about 180° such that the geometric shapes of the edge pieces are equally oriented or aligned.

According to some embodiments, the positioning device 620 is tiltable, for example, with respect to the first direction 1 and/or a horizontal plane. As an example, the positioning device 620 can tilt the solar cell piece held by the positioning device 620 to align an orientation of the solar cell piece with respect to another solar cell piece on the support device 630 with which the solar cell piece held by the positioning device 620 is to be overlapped. In particular, the back side or back side plane of the solar cell piece held by the positioning device 620 can be oriented to be substantially parallel to a front side or front side plane of the other solar cell piece on the support device 630. In some implementations, the positioning device 620 is configured to align a back side contact of the solar cell piece with respect to a front side contact, such as a busbar, of another solar cell piece on the support device 630 such that an electrical contact between the back side contact and the front side contact can be established, for example, with an adhesive provided therebetween.

As shown in FIG. 8, a plurality of solar cell pieces can be positioned on the support device 630 in an overlapping manner to form the solar cell arrangement, which can be a shingled solar cell. At least some of the plurality of pieces originate from at least two different solar cells. In particular, the solar cell pieces can be sorted and individually be allocated to a respective solar cell arrangement, for example, based on one or more properties, such as geometric and/or physical properties, of the respective solar cell piece.

In some implementations, the support device 630 is a belt conveyor having the one or more second belts 632. A movement of the belt conveyor, and in particular of the one or more second belts 632, and a movement of the at least one positioning device 620 can be synchronized with each other, for example, during the assembling of the at least two solar cell arrangements on the support device 630. Additionally or alternatively, a movement of the transport device 650, for example, the one or more first belts 652, and a movement of the at least one positioning device 620 and/or the one or more second belts 632 can be synchronized with each other. By synchronizing at least some of the movements, a continuous process flow for assembling of the at least two solar cell arrangements can be provided.

According to some embodiments, which can be combined with other embodiments described herein, the system further includes a heating device 660, for example, at or above the support device 630. The heating device 660 can be configured to heat at least one of the solar cell arrangements on the support device 630, such as the first solar cell arrangement and/or the second solar cell arrangement. The heating device 660 can be selected from the group consisting of conduction heaters (e.g., hot plates), convective heaters, resistive heaters, infrared heaters, lamp heaters, hot air heaters, and any combination thereof. As an example, the support device 630 can be configured as a hot plate for conduction heat transfer to heat the solar cell arrangement(s) on the support device 630.

In some implementations, the heating device 660 can extend along at least a portion of the support device 630, for example, in the transport direction 4 in which the solar cell arrangements are conveyed by the support device 630. The heating device 660 can extend along a distance sufficient to dry the adhesive used for electrically connecting adjacent overlapping solar cell pieces, such as the silver paste or solder. The heating device 660 can have two or more heating elements provided in parallel at the support device 630. As an example, a first heating element can be configured to heat the first solar cell arrangement. A second heating element can be configured to heat the second solar cell arrangement. In particular, according to some embodiments, the heating device 660 can extend above the support device 630 at positions corresponding to positions of the at least two solar cell arrangements. For example, the first heating element can be arranged above the first solar cell arrangement, and the second heating element can be arranged above the second solar cell arrangement.

The heating device 660 can be configured to provide a predetermined temperature at the position of at least a portion of the solar cell arrangement. The predetermined temperature can be at least 100° C., specifically at least 150° C., and more specifically at least 300° C. The predetermined temperature can be in a range of between 100° C. and 400° C., and can be specifically in a range of between 100° C. and 200° C.

The solar cells that are divided into the two or more solar cell pieces can be selected from the group consisting of full-square solar cells and pseudo-square solar cells. The full-square solar cell can be, for example, a quadratic multi-crystalline wafer cut from silicon ingots. The pseudo-square solar cell can be a squared wafer with rounded edges cut from monocrystalline silicon ingots. In comparison with the full-square solar cell, the pseudo-square solar cell can be beneficial in that less waste is produced during the manufacturing process.

The individual pieces of the solar cells can be allocated to different solar cell arrangements based on the geometrical shape. As an example, the (edge) pieces of the pseudo-square solar cell having the rounded edges (“pseudo-square pieces”) can be allocated to one solar cell arrangement, for example, the first solar cell arrangement. The (middle) piece(s), which are full-square pieces, can be allocated to another solar cell arrangement, for example, the second solar cell arrangement. Specifically, solar cell arrangements having only full-square pieces or only pseud-square pieces are provided. “Bottlenecks” caused by a pseud-square piece in a solar cell arrangement having otherwise full-square pieces can be avoided and an efficiency of the solar cell arrangement can be increased.

According to some embodiments, which can be combined with other embodiments described herein, the solar cells, such as the full-square solar cell and/or pseudo-square solar cell, can be separated or divided at positions adjacent to the busbars of the respective solar cell. In other words, each solar cell piece can have a busbar, and particularly only one busbar, provided thereon, which can be located at an edge of the solar cell piece.

FIG. 9A shows a schematic view of a production system 700 for the manufacture of at least one shingled solar cell according to embodiments described herein. The production system 700 can be part of, or constitute, a production line for shingled solar cells.

The production system 700 includes the system for the manufacture of at least one solar cell arrangement, which can be a shingled solar cell arrangement, according to the embodiments described herein. The production system 700 further includes a production tool 710 for manufacturing a plurality of solar cells including the first solar cell. The plurality of solar cells are input into the system for the manufacture of at least one solar cell arrangement which includes the apparatus 730 for separating a solar cell into two or more solar cell pieces of the present disclosure, the positioning device 740, and the support device 750 according to the embodiments described therein.

In some implementations, the production tool 710 includes one or more printing devices configured for printing one or more conductive lines on solar cell substrates used in the manufacture of the plurality of solar cells. The one or more conductive lines are selected from fingers and busbars. The one or more printing devices can be configured for double printing of the one or more conductive lines. Specifically, the one or more printing devices can be configured for double printing of at least one of the fingers and busbars.

According to some embodiments, the production system 700 includes an adhesive application device 720 configured to apply an adhesive to the solar cell before the solar cell is separated into the two or more solar cell pieces. The adhesive is applied to portions of the solar cell corresponding to an overlapping region between two adjacent solar cell pieces that are arranged on the support device 750 in an overlapping manner. According to some embodiments, the adhesive application device 720 can be configured to apply the adhesive on at least a portion of the conductive line pattern, such as the busbars, of the solar cell.

According to some embodiments, which can be combined with other embodiments described herein, the apparatus 730 includes the at least one solar cell perforation device. For example, the at least one solar cell perforation device includes, or is, a laser. As an example, the at least one solar cell perforation device can be configured to perforate the solar cell before the solar cell is separated into the two or more solar cell pieces.

In some implementations, the production system 700 further includes a heating device 760, for example, subsequent to, or above, the support device 750. An embodiment of the heating device 760 is described with respect to FIG. 8. In particular, the heating device 760 can be configured to heat at least one of the solar cell arrangements to dry the adhesive in the overlapping region between two adjacent solar cell pieces. The heating device 760 can be selected from the group consisting of conduction heaters (e.g., hot plates), convective heaters, resistive heaters, infrared heaters, lamp heaters, hot air heaters, and any combination thereof.

According to some embodiments, which can be combined with other embodiments described herein, the production system 700 includes a sorting device 770 configured for sorting the at least two solar cell arrangements, such as the first solar cell arrangement and the second solar cell arrangement, based on a quality determination of the at least two solar cell arrangements. As an example, solar cell arrangements which are defective or have a low quality can be discarded. Optionally, defective solar cell arrangements can undergo a reworking or repair process, for example, to replace defective or low-quality solar cell pieces.

FIG. 9B shows a schematic view of a production system 800 for the manufacture of at least one shingled solar cell arrangements, such as two or more shingled solar cell arrangements, according to further embodiments described herein. The production system 800 is similar to the system described with respect to FIG. 9A, and a description of similar or identical aspects is not repeated. In particular, the production system 800 includes the production tool 810, the adhesive application device 820, the heating device 860, and a sorting device 870.

According to some embodiments, which can be combined with other embodiments described herein, the production system 800 includes an inspection arrangement. The inspection arrangement can include at least one of a first inspection device 815, a second inspection device (may be included in the apparatus of the present disclosure, for example, in the positioning device 840), and a third inspection device 865.

The first inspection device 815, the second inspection device, and the third inspection device 865 can be configured to determine and/or measure one or more properties, such as geometric and/or physical properties, of at least one of the solar cell, solar cell pieces and/or solar cell arrangement as described with respect to the embodiments described herein. In particular, the one or more properties can be selected from the group consisting of geometric shape, electrical properties, optical properties, printing quality, and any combination thereof.

In some implementations, the first inspection device 815 is configured to measure and/or determine one or more properties of a solar cell before the solar cell is separated into two or more solar cell pieces. Although the first inspection device 815 is exemplarily illustrated as being positioned between the production tool 810 and the adhesive application device 820, the present disclosure is not limited thereto. For example, the first inspection device 815 can be provided between the adhesive application device 820 and the apparatus of the present disclosure or can be integrated into the production tool 810, the adhesive application device 820, or the separation device 830. The apparatus of the present disclosure can be included in the separation device 830.

According to some embodiments, the second inspection device is configured to measure and/or determine one or more properties of at least some of the solar cell pieces after the solar cell has been separated into pieces. The second inspection device can be integrated into the apparatus, for example, in the apparatus or the positioning device 840. In further implementations, the second inspection device can be provided as a separate entity.

In some embodiments, the third inspection device 865 is configured to measure and/or determine one or more properties of the at least one solar cell arrangement, such as the first solar cell arrangement and/or the second solar cell arrangement. Although the third inspection device 865 is exemplarily illustrated as being positioned between the heating device 860 and the sorting device 870, the present disclosure is not limited thereto. For example, the third inspection device 865 can be provided at the support device 850. In some implementations, the support device 850, the heating device 860, and the third inspection device 865 are integrated in a single entity or process station.

The present disclosure mechanically holds and separates a solar cell. The holding device and the separation device are moved together to hold and separate the solar cell. The holding device is biased such that a predetermined holding force is exerted on the solar cell. A well-defined, smooth and accurate breaking edge can be achieved. A quality of the solar cell pieces used to assemble a solar cell arrangement, such as a shingled solar cell arrangement, can be improved and an output power can be increased.

While the foregoing is directed to embodiments of the disclosure, other and further embodiments of the disclosure may be devised without departing from the basic scope thereof, and the scope thereof is determined by the claims that follow.

1. An apparatus for separating a solar cell into two or more solar cell pieces, comprising:
a moveable arrangement;
a separation device attached to the moveable arrangement; and
a holding device attached to the moveable arrangement via one or more elastic elements.

2. The apparatus of claim 1, further including at least one actuator configured to move the moveable arrangement at least in a first direction perpendicular to a surface of the solar cell.

3. The apparatus of claim 2, wherein the first direction is a vertical direction.

4. The apparatus of claim 1, wherein the separation device is immovably attached to the moveable arrangement.

5. The apparatus of claim 1, wherein the holding device is configured to be moveable with respect to the moveable arrangement.

6. The apparatus of claim 1, wherein the one or more elastic elements are configured to provide a holding force for holding the solar cell at a support arrangement.

7. The apparatus of claim 1, wherein the one or more elastic elements are springs.

8. The apparatus of claim 1, wherein:
the moveable arrangement has one moveable body, and wherein the separation device and the holding device are attached to the one moveable body, or
the moveable arrangement has a first moveable body and a second moveable body, wherein the separation device is attached to the first moveable body and the holding device is attached to the second moveable body, and wherein the first moveable body and the second moveable body are moveable independently from each other.

9. The apparatus of claim 1, wherein the separation device is configured to mechanically contact a first surface of a solar cell to divide the solar cell into two or more solar cell pieces, and wherein the holding device is configured to mechanically contact the first surface of the solar cell to hold the solar cell at a support arrangement while the solar cell is divided into the two or more solar cell pieces.

10. The apparatus of claim 9, wherein the holding device includes an elastic contact element configured to mechanically contact the first surface of the solar cell.

11. A system for the manufacture of at least one shingled solar cell arrangement, including:
the apparatus of claim 1; and
a support arrangement, wherein the support arrangement includes at least one of a first support configured for supporting the solar cell and a second support configured for supporting at least one solar cell piece of the two or more solar cell pieces.

12. The system of claim 11, wherein the first support is a first transportation device configured for transportation of the solar cell to the separation device, and wherein the second support is a second transportation device configured for transportation of the two or more solar cell pieces away from the separation device.

13. The system of claim 11, further including at least one positioning device configured for positioning the two or more solar cell pieces on a support device to assemble the at least one shingled solar cell arrangement.

14. A method for separating a solar cell into two or more solar cell pieces, comprising:
moving a moveable arrangement towards the solar cell;
contacting a first portion of a first surface of the solar cell with a holding device attached to the moveable arrangement via one or more elastic elements; and
after contacting the first portion with the holding device, contacting a second portion of the first surface with a separation device attached to the moveable arrangement to divide the solar cell into the two or more solar cell pieces.

15. The method of claim 14, wherein the separation device is immoveable with respect to the moveable arrangement and the holding device is moveable with respect to the moveable arrangement.

16. The apparatus of claim 2, wherein the separation device is immovably attached to the moveable arrangement.

17. The apparatus of claim 3, wherein the separation device is immovably attached to the moveable arrangement.

18. The apparatus of claim 2, wherein the holding device is configured to be moveable with respect to the moveable arrangement.

19. The apparatus of claim 3, wherein the holding device is configured to be moveable with respect to the moveable arrangement.

20. The apparatus of claim 4, wherein the holding device is configured to be moveable with respect to the moveable arrangement.
